(19) United States
(12) Patent Application Publication
(10) Pub. No.: US 2009/0115484 A1
(43) Pub. Date: May 7, 2009

(54) DIGITALLY CONTROLLED DELAY ELEMENT

(76) Inventor: GEORGE ALEXANDER, Durham, NC (US)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/933,875

(22) Filed: Nov. 1, 2007

(51) Int. Cl. H03H 11/26

(52) U.S. Cl. 327/261

(57) ABSTRACT

Techniques and corresponding circuits for achieving programmable delay with linear resolution are provided. The techniques provide for incremental delay with substantially equal increments. Linear resolution may be achieved through the use of a circuit arrangement that allows current to be controlled to linearly vary effective resistance of a delay circuit, without affecting the effective capacitance.

### BACKGROUND OF THE INVENTION

### Description of the Related Art

Programmable delay elements are often utilized in computing systems to achieve a desired relationship between externally supplied control signals, such as a clock signal, and corresponding internally generated control signals. Conventional programmable delay elements often suffer from non-monotonically increasing delay, such that each incremental change in delay is not equal. As a result, achieving a desired delay using such circuits may be difficult.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a programmable delay element according to an embodiment of the present invention.

FIG. 2 illustrates a programmable delay element according to an embodiment of the present invention.

FIG. 3 illustrates a programmable delay element according to another embodiment of the present invention.

FIG. 4 illustrates a programmable delay element according to another embodiment of the present invention (multiple input programmable delay).

FIG. 5 illustrates a memory device using a programmable delay element according to an embodiment of the present invention.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Also, signal names used below are exemplary names, indicative of signals used to perform various functions in a given memory device. In some cases, the relative signals may vary from device to device. Furthermore, the circuits and devices described below and depicted in the figures are merely exemplary of embodiments of the invention. As recognized by those of ordinary skill in the art, embodiments of the invention may be utilized with any memory device.

Embodiments of the invention may generally be used with any type of memory. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In another embodiment, the memory may be provided as a memory device which is used with a separate memory controller device or processor device.

In both situations, where the memory is integrated into a device with other circuits and where the memory is provided as a separate device, the memory may be used as part of a larger computer system. The computer system may include a motherboard, central processor, memory controller, the memory, a hard drive, graphics processor, peripherals, and any other devices which may be found in a computer system. The computer system may be part of a personal computer, a server computer, or a smaller system such as an embedded system, personal digital assistant (PDA), or mobile phone.

In some cases, a device including the memory may be packaged together with other devices. Such packages may include any other types of devices, including other devices with the same type of memory, other devices with different types of memory, and/or other devices including processors and/or memory controllers. Also, in some cases, the memory may be included in a device mounted on a memory module. The memory module may include other devices including memories, a buffer chip device, and/or a controller chip device. The memory module may also be included in a larger system such as the systems described above.

In some cases, embodiments of the invention may be used with multiple types of memory or with a memory which is included on a device with multiple other types of memory. The memory types may include volatile memory and non-volatile memory. Volatile memories may include static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other types of nonvolatile memory.

Embodiments of the invention generally provide techniques for achieving accurate control of programmable delays. The programmable delay may be controlled to provide uniform or non-uniform resolution. For example, the techniques may provide for incremental delay with substantially equal increments. For some embodiments, linear resolution may be achieved by controlling the current to linearly vary effective resistance of a delay circuit, without affecting the effective capacitance. In other embodiments, non-uniform resolution may be achieved by utilizing the non-linear charge sharing effect created by the effective capacitance to change the overall delay of the circuit. The techniques described herein may be utilized in a wide variety of applications that benefit from programmable delay. As an example, memory devices, such as dynamic random access memory (DRAM) devices, often utilize programmable delay elements in delay locked loops (DLLs) and/or phase locked loops (PLLs) used to achieve a desired relationship between externally supplied control signals (e.g., clock or data strobe signals) and corresponding internally generated control signals used to access (read/write) storage elements of the memory device. However, those skilled in the art will recognize a variety of other applications in which the techniques provided herein may be utilized, such as central processor units (CPUs), graphics processor units (GPUs), digital signal processors (DSPs), and the like.

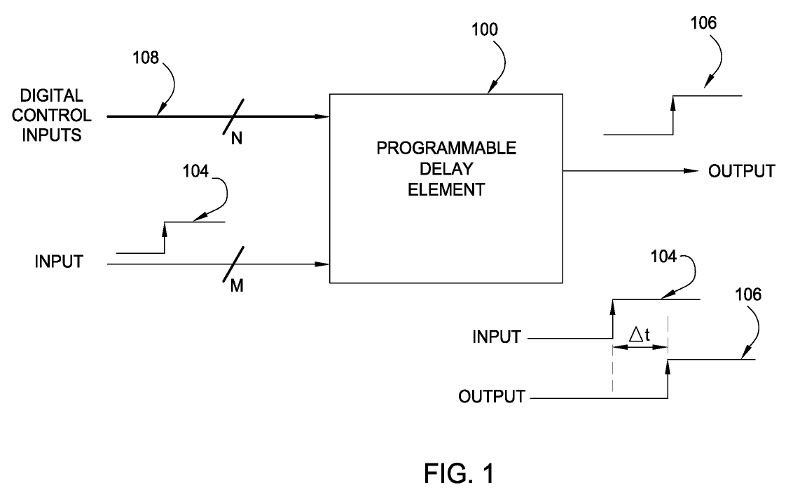

FIG. 1 illustrates an embodiment of a programmable delay element 100. As illustrated, the programmable delay element generates an output signal 106 that is delayed, relative to an input signals 104, by a delay amount (labeled Δt in the Figure). The delay amount is programmable, with the total delay time depending on the values of digital control input signals 108.

The programmable delay element 100 may be arranged to achieve a substantially linear delay. In other words, the arrangement may be designed such that the amount of delay may be varied based on an input “code” formed by the value of the digital control signals 108. The amount of delay may be varied according to application requirements. For example, the amount of delay may be varied in substantially equal increments, if desired. In addition, the programmable delay element 100 may be arranged to achieve a non-linear delay.

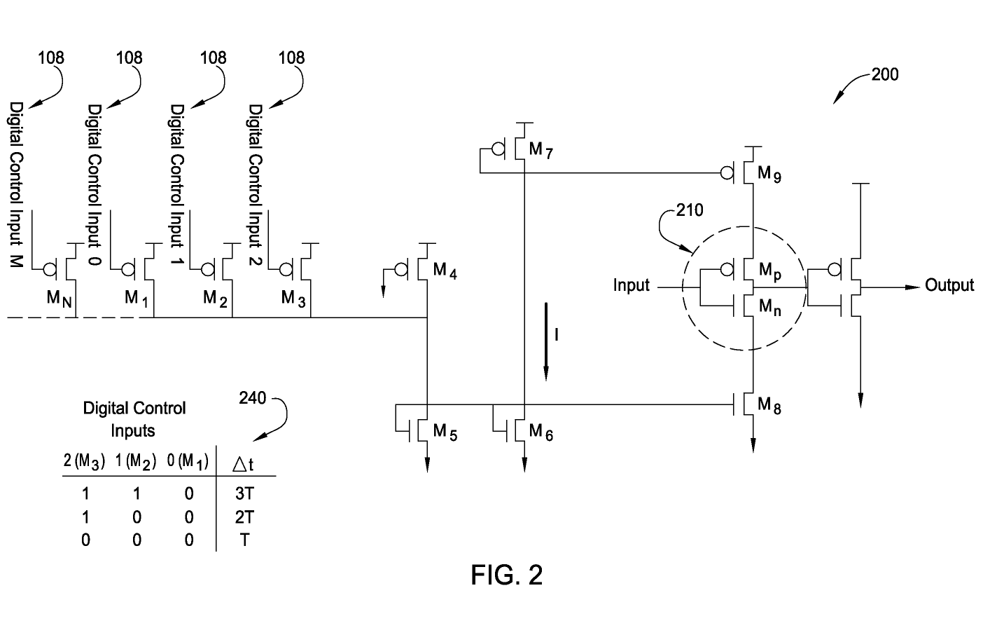

One such arrangement 200 is illustrated in FIG. 2. As illustrated, an N number of control signals 108 (digital control input [n:0]) are shown. Therefore, the number of control signals may change according to the needs of a particular application.

Accordingly, FIG. 2 illustrates an embodiment of a programmable delay element where transistors M1, M2, M3 and M_{N} are switched on or off via the digital control inputs 108 to control the strength of a controlling current (I). The controlling current (I) can then be mirrored to transistors M8 and M9 and control the delay of the inverter 210.

As the controlling current is increased by switching more digital control inputs 108 on, the effective resistance across transistors M8 and M9 is reduced, thus decreasing the delay of the circuit. In order for the transistors to exhibit the resistor-like behavior, they may be kept in a linear region mode of operation (e.g., not saturated). Furthermore, since the number of transistors at the source and drain of Mp and Mn, respectively, is fixed (at one in the illustrated example), the parasitic capacitance at Mp and Mn is kept constant regardless of the number of transistors M1-M_{N} that are switched on. As a result, non-linearities resulting from a charge sharing effect may be avoided.

FIG. 2 only illustrates one embodiment of the delay circuit that can generate a constant current. Other embodiments may use types of constant current sources known in the art. It is only necessary that the source allows the current to be manipulated via the control signal inputs 108.

Thus, by selectively switching successive transistors, the resulting delay may change. The truth table 240 in FIG. 2 illustrates how the delay of the circuit (Δt) decreases incrementally as the number of enabled transistors increases. For example, when only one transistor is switched on (where a logic level of 0 represents on), Δt is equal to 3T. When two transistors are switched on, Δt is equal to 2T. Finally, when all transistors are switched on, Δt is equal to T. As stated earlier, as more transistors are switched on, the delay of the circuit incrementally decreases.

The truth table 240 in FIG. 2 also illustrates how the delay of the circuit (Δt) increases incrementally as the number of enabled transistors decreases. For example, when all the transistors are switched on, Δt is equal to T. When only two transistors are enabled, Δt is equal to 2T. Finally, when only one transistor is enabled, Δt is equal to 3T.

The example in FIG. 2 assumes transistors of the same size, resulting in an equal amount of additional current (and corresponding delay) for each transistor switched on. However, for some embodiments the transistors used to control bias current may include transistors having different sizes.

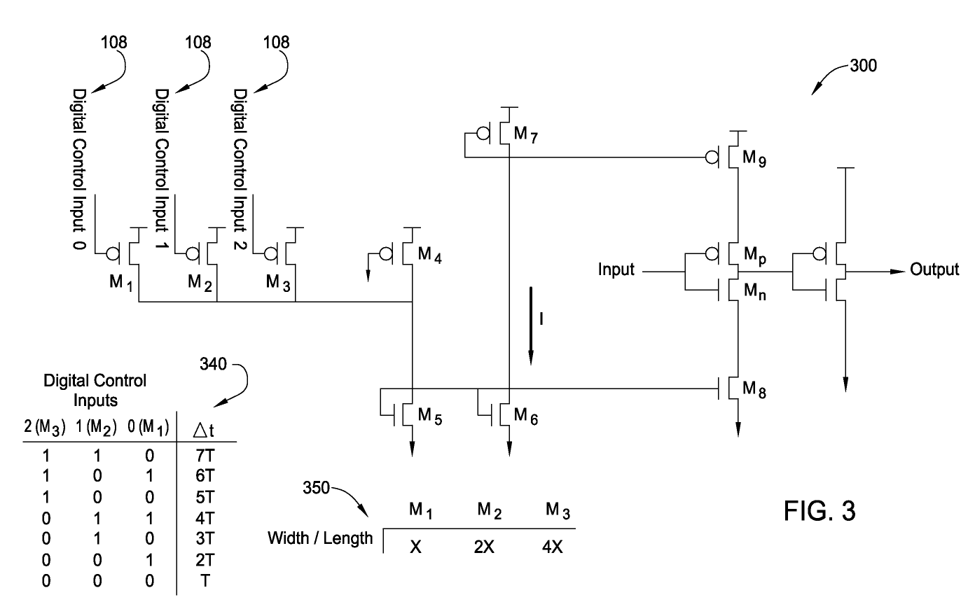

For example, FIG. 3 illustrates an arrangement 300 of transistors, where transistors M1, M2 and M3 are sized differently, which may allow more granularity of delay. Only three transistors are shown in FIG. 3 for ease of description. For one embodiment, M1, M2 and M3 may have dimensions selected in an effort to provide a desired relationship between current contributions for each transistor. For example, as illustrated in Table 350, the geometrical aspect ratio (width/length) of M1-M3 may be selected to provide proportional current contributions for M1-M3. As illustrated, assuming M1 has an aspect ratio of W/L, M2 may be twice the size of M1 (2× W/L), and the aspect ratio of M3 may be twice the size of M2 (4× W/L). As a result, a range of different delay values may be generated by varying the 3-bit control code.

The truth table 340 in FIG. 3 illustrates how Δt decreases incrementally as differently-sized transistors are switched on and off. For example, when only M1 is switched on (where a logic level of 0 represents on), Δt is equal to 7T. When only M2 is switched on, Δt is equal to 6T. When M1 and M2 are switched on, Δt is equal to 5T, etc. Therefore, by utilizing differently-sized transistors in the programmable delay element, a finer granularity of delay can be attained.

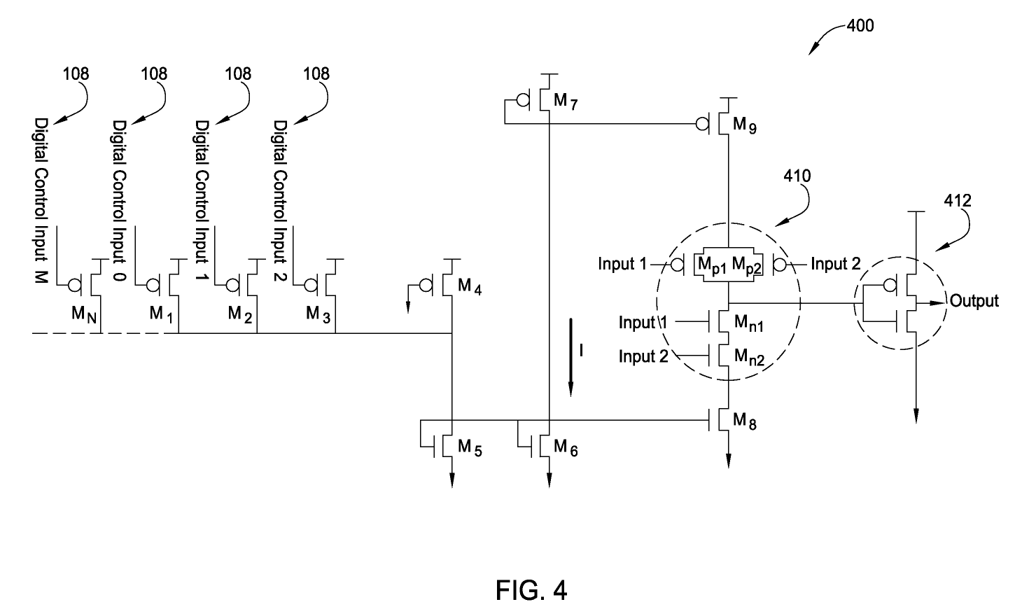

While the example above illustrates generating a delayed version of an input signal, other embodiments of a programmable delay element may be utilized in other types of logic. For example, FIG. 4 illustrates a programmable delay element for a logic circuit utilizing multiple inputs.

In this embodiment, a programmable delay is provided for a two-input AND operation by variably-delaying a NAND gate 410 (using similar techniques to vary the delay as described above) and supplying the output of the NAND gate to an inverter 412, thus effectively creating a variably-delayed AND operation. For example, when both inputs of the NAND gate 410 are equal to one (a logic high in this example), series pull down transistors MN1 and MN2 will be turned on and the output of the NAND gate 410 will be zero. For all other permutations of Input 1 and Input 2, at least one of the series pull down transistors is not turned on and the output of the NAND gate 410 will be one. This behavior is the opposite of an AND operation. Therefore, an inverter 412 can be provided at the output of the NAND gate 410 to achieve the behavior of an AND operation.

Embodiments of the delay circuit may also include a programmable option to enable or disable the delay circuit. For example, one embodiment may use a tri-state buffer, where the constant current is the input, and a programmable input is the control. The circuit can be enabled by switching the programmable control input on, thus allowing the constant current to pass through the buffer and to the rest of the circuit. Alternatively, the programmable control input may be switched off, thus excluding the constant current from the circuit, effectively disabling the delay circuit.

Embodiments of the present invention may be utilized in a variety of applications to vary a delay between an input signal and an output signal generated as a delayed version of the input signal. Utilizing techniques described above, a constant bias may be applied to operate controlling transistors of a delay element in an analog manner (keeping the transistors operating in a linear region and avoiding saturation). Such techniques may be particularly well suited for use in applications where low voltage and high speed are desired.

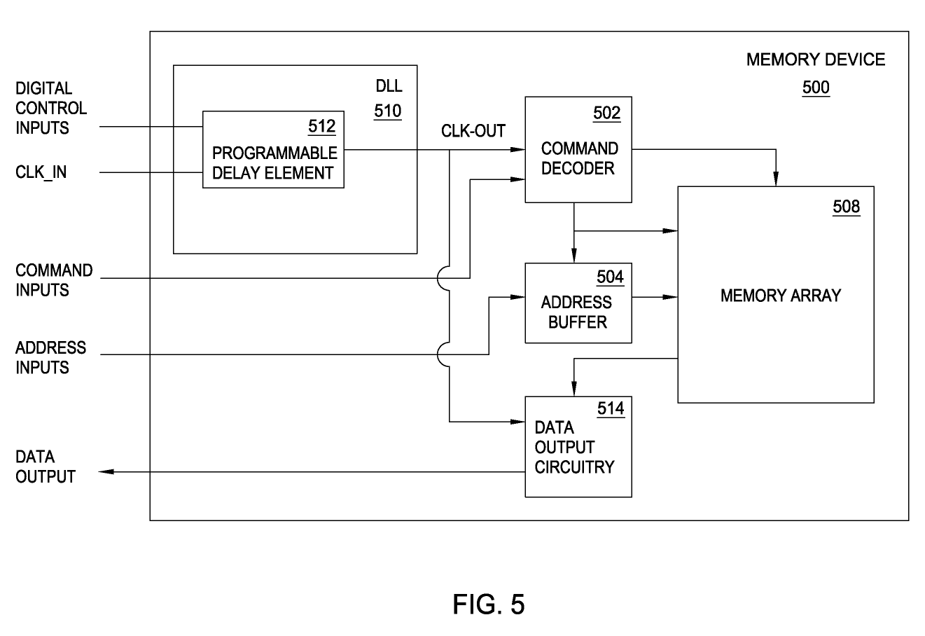

As stated earlier, memory devices often utilize programmable delay elements in delay locked loops (DLLs) to achieve a desired relationship between externally supplied control signals (e.g., clock or data strobe signals) and corresponding internally generated control signals used to access (read/write) storage elements of the memory device. For such an embodiment, as illustrated in FIG. 5, the memory device 500 may include a DLL 510 that contains a programmable delay element 512. The programmable delay element 512 may receive an external clock (CLK_IN) as its input. CLK_IN can subsequently be delayed, using the techniques described above, and then outputted (CLK_OUT) from the programmable delay element 512 and to control logic, such as a command decoder 502 and data output circuitry 514 (described below), of the memory device 500.

The memory device 500 may also include address inputs and command inputs. The address inputs may be received by an address buffer 504, and the command inputs may be received by the command decoder 502. The command inputs and the address inputs may be used to access memory cells (containing data) within a memory array 508. Circuitry such as a wordline decoder, column decoder, sense amps, output buffers, data strobe circuits, may also be used to access and output data from the memory array 508. The memory device 500 may also contain data output circuitry 506, used to latch data onto the output terminals of the memory device 500.

While the foregoing is directed to embodiments of the present invention, other and further embodiments of the invention may be devised without departing from the basic scope thereof, and the scope thereof is determined by the claims that follow.

1. A programmable delay circuit, comprising:
a delay element having an arrangement of one or more control transistors for generating, as an output, a delayed version of an input signal; and
a plurality of bias transistors arranged to provide a controlling current to the delay element, wherein each transistor is selectively switched by one of a plurality of digital input signals forming a control code, to vary an effective resistance of one or more control transistors of the delay element without substantially varying an effective capacitance of the arrangement of control transistors.

2. The programmable delay circuit of claim 1, wherein the plurality of bias transistors have substantially equal width to length aspect ratios.

3. The programmable delay circuit of claim 1, wherein the plurality of bias transistors comprise at least two transistors with proportionally increasing width to length aspect ratios.

4. The programmable delay circuit of claim 1, wherein the plurality of bias transistors comprise at least four transistors.

5. The programmable delay circuit of claim 1, wherein the plurality of bias transistors are arranged to allow the effective resistance of the arrangement of control transistors to be varied in substantially equal increments.

6. The programmable delay circuit of claim 1, further comprising a decoder for generating the digital input signals forming the control code from a set of control signals fewer in number than the digital input signals.

7. An integrated circuit, comprising:
an input for receiving an external signal; and
a delay element having an arrangement of one or more control transistors for generating a delayed version of the external signal; and
a plurality of bias transistors arranged to provide a controlling current to the delay element, wherein each transistor is selectively switched by one of a plurality of digital input signals forming a control code, to vary an effective resistance of one or more control transistors of the delay element without substantially varying an effective capacitance of the arrangement of control transistors.

8. The integrated circuit of claim 7, wherein the plurality of bias transistors are arranged to allow the effective resistance of the arrangement of control transistors to be varied in substantially equal increments.

9. The integrated circuit of claim 8, wherein the plurality of bias transistors are arranged to allow the effective resistance of the arrangement of control transistors to be varied in N substantially equal increments, wherein N is greater than the number of control transistors.

10. The integrated circuit of claim 7, wherein the integrated circuit is a memory device and further comprises:
an array of storage elements; and
the delay element has an arrangement of one or more control transistors for generating a delayed version of an externally supplied control signal for use in accessing the storage elements.

11. A method, comprising:
receiving an input signal;
generating an output signal that is a delayed version of the input signal; and
varying a delay between the input signal and the delayed versions by varying an effective resistance of an arrangement of transistors without varying an effective capacitance of the capacitance of the arrangement of transistors.

12. The method of claim 11, wherein varying a delay between the input signal and the delayed versions by varying an effective resistance of an arrangement of transistors without varying an effective capacitance of the capacitance of the arrangement of transistors comprises selectively switching a plurality of bias transistors based on a control code.

13. The method of claim 12, further comprising generating the control code based on a set of control signals having fewer bits than the control code.

14. The method of claim 12, wherein the bias transistors have substantially equal width to length aspect ratios.

15. The method of claim 12, wherein the plurality of bias transistors comprise at least two transistors with proportionally increasing width to length aspect ratios.

16. The method of claim 12, wherein the plurality of bias transistors comprise at least four transistors.

17. The method of claim 12, wherein varying the effective resistance of the arrangement of control transistors comprises selectively switching the plurality of bias transistors to be vary the effective resistance in substantially equal increments.

18. The method of claim 17, wherein varying the effective resistance of the arrangement of control transistors comprises selectively switching M transistors capable of varying the effective resistance in N substantially equal increments, where N=2M.

19. A logic device, comprising:
a logic circuit that generates an output signal that varies when a logic condition based on at least two logic input signals is satisfied; and
a delay element having an arrangement of one or more control transistors for generating a delayed version of the output signal; and
a plurality of bias transistors arranged to provide a controlling current to the delay element, wherein each transistor is selectively switched by one of a plurality of digital input signals forming a control code, to vary an effective resistance of one or more control transistors of the delay element without substantially varying an effective capacitance of the arrangement of control transistors.

20. The logic device of claim 19, wherein the logic circuit implements a NAND function based on the at least two logic input signals.
